(19) United States
(12) Patent Application Publication
(10) Pub. No.: US 2006/0204762 A1
(43) Pub. Date: Sep. 14, 2006

(54) Liquid epoxy resin composition and semiconductor device

(76) Inventors: Kazuaki Sumita, Gunma-ken (JP); Shingo Ando, Gunma-ken (JP); Toshio Shiobara, Gunma-ken (JP)

Correspondence Address: BIRCH STEWART KOLASCH & BIRCH, PO BOX 747, FALLS CHURCH, VA, 22040-0747, US

(21) Appl. No.: 11/429,265

(22) Filed: May 8, 2006

Related U.S. Application Data
(62) Division of application No. 10/618,765, filed on Jul. 15, 2003.

(30) Foreign Application Priority Data
Jul. 18, 2002 (JP) 2002-209437

(51) Int. Cl. B32B 27/38; C08L 63/00; C08L 83/00; H01L 21/56; B32B 37/00

(52) U.S. Cl. 428/413; 428/447; 525/476; 438/127

(57) ABSTRACT

A liquid epoxy resin composition comprising a liquid epoxy resin, a curing agent, and an inorganic filler is useful for semiconductor encapsulation when the curing agent contains 5-100% by weight of a specific aromatic amine compound of at least 99% pure, the epoxy resin and the curing agent are present in a molar ratio from 0.7 to 0.9, and the composition has a toughness K_{1c} of at least 3.5. The composition is adherent to the surface of silicon chips, does not deteriorate under hot humid conditions, and is fully resistant to thermal shocks.

This application is a Divisional of co-pending application Ser. No. 10/618,765, filed on Jul. 15, 2003, the entire contents of which are hereby incorporated by reference and for which priority is claimed under 35 U.S.C. § 120.

This invention relates to a liquid epoxy resin composition for semiconductor encapsulation, and more particularly, to a liquid epoxy resin composition which has improved adhesion to the surface of silicon chips and especially photosensitive polyimide resins, nitride films and oxide films, and cures into a product having improved resistance to humidity and to thermal shocks at high temperatures above the reflow temperature of 260° C., and is thus suitable as encapsulation material. It also relates to a semiconductor device which is encapsulated with the liquid epoxy resin composition.

### BACKGROUND OF THE INVENTION

The trend toward smaller sizes, lighter weights and increased capabilities in electrical equipment has led to a shift in the dominant semiconductor mounting process from pin insertion to surface mounting. Progress of semiconductor devices toward a higher degree of integration entails the enlargement of dies to a size as large as 10 mm or more per side. For semiconductor devices using such large size dies, greater stresses are applied to the die and the encapsulant during solder reflow. Such stresses are problematic because separation occurs at the interface between the encapsulant and the die or substrate, and the package cracks upon substrate mounting.

From the expectation that the use of leaded solders will be banned in the near future, a number of lead-substitute solders have been developed. Since most substitute solders have a higher melting temperature than the leaded solders, it has been considered to carry out reflow at temperatures of 260 to 270° C. At such reflow temperatures, more failures are expected with encapsulants of prior art liquid epoxy resin compositions. Even with flip chip type packages which have raised no substantial problems in the prior art, the reflow at such high temperatures brings about serious problems that cracks can occur during the reflow and the encapsulant can peel at interfaces with chips or substrates.

### SUMMARY OF THE INVENTION

An object of the invention is to provide a liquid epoxy resin composition for semiconductor encapsulation which cures into a cured product that has improved adhesion to the surface of silicon chips and especially photosensitive polyimide resins and nitride films and improved toughness, does not suffer a failure even when the temperature of reflow elevates from the conventional temperature of nearly 240° C. to 260-270° C., does not deteriorate under hot humid conditions as encountered in PCT (120° C./2.1 atm), and does not peel or crack over several hundred cycles of thermal cycling between −65° C. and 150° C. Another object of the invention is to provide a semiconductor device which is encapsulated with a cured product of the liquid epoxy resin composition.

The invention pertains to a liquid epoxy resin composition comprising (A) a liquid epoxy resin, (B) an aromatic amine curing agent, and (C) an inorganic filler. It has been found that better results are obtained when the aromatic amine curing agent (B) contains at least 5% by weight based on the entire curing agent of at least one aromatic amine compound having a purity of at least 99% selected from compounds having the following general formulae (1) to (3): 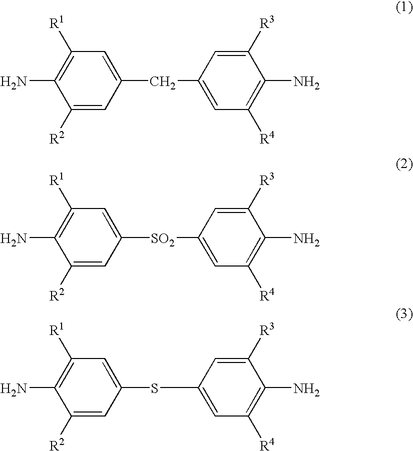
wherein each of R¹ to R⁴ is hydrogen or a monovalent hydrocarbon group having 1 to 6 carbon atoms, the liquid epoxy resin (A) and the aromatic amine curing agent (B) are present in a molar ratio (A)/(B) from 0.7/1 to 0.9/1, and theses components are compounded such that the composition has a toughness K_{1c} of at least 3.5. The resulting liquid epoxy resin composition is effectively adherent to the surface of silicon chips and especially photosensitive polyimide resins and nitride films, does not deteriorate under hot humid conditions as encountered in PCT (120° C./2.1 atm), and is fully resistant to thermal shocks. The composition is thus suited as an encapsulant for large die size semiconductor devices.

Aromatic amine curing agents are per se known for semiconductor encapsulants. In particular, Japanese Patent No. 3,238,340 and JP-A 10-158366 disclose amine curing agents analogous to the aromatic amine curing agents of the formulae (1) to (3) used in the present invention. With respect to the molar ratio of epoxy resin to curing agent, JP-A 10-158366 describes that in a curing agent excess situation that the epoxy resin is not more than 0.9 mole per mole of the curing agent, unreacted amino groups are left in excess, resulting in a lowering of humidity resistance and reliability. The inventors have found that when the epoxy resin and the aromatic amine curing agent of formulae (1) to (3) are used in a molar ratio between 0.7 and 0.9, the liquid epoxy resin composition becomes effectively adherent to the surface of silicon chips and especially photosensitive polyimide resins and nitride films, and significantly resistant to thermal shocks, and maintains satisfactory properties under hot humid conditions. The prior art compositions comprising epoxy resin and amine curing agent contain a silane coupling agent as an essential component, which causes voids to generate when the resin compositions are poured or cured for the manufacture of flip chip semiconductor devices. To solve the voiding problem, the composition of the present invention is formulated such that the composition absent a silane coupling agent is highly reliable and effective as an encapsulant especially for large die size semiconductor devices.

Therefore, the present invention provides a liquid epoxy resin composition comprising (A) a liquid epoxy resin, (B) an aromatic amine curing agent, and (C) an inorganic filler, wherein the aromatic amine curing agent (B) comprises at least 5% by weight based on the entire curing agent of at least one aromatic amine compound having a purity of at least 99% selected from compounds having the general formulae (1) to (3), the liquid epoxy resin (A) and the aromatic amine curing agent (B) are present in a molar ratio (A)/(B) from 0.7/1 to 0.9/1, and the composition has a toughness K_{1c} of at least 3.5.

### BRIEF DESCRIPTION OF THE DRAWING

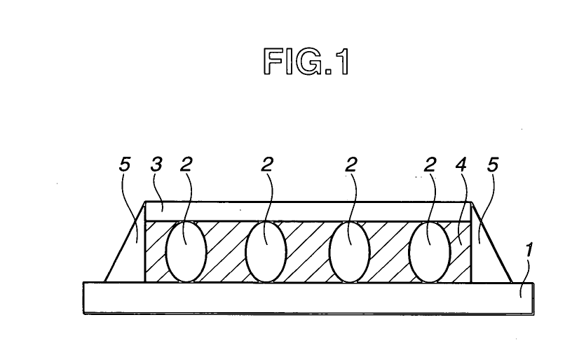

The only FIGURE, FIG. 1 is a schematic view of a flip chip-type semiconductor device according to one embodiment of the invention.

### DESCRIPTION OF THE PREFERRED EMBODIMENTS

In the liquid epoxy resin composition of the invention serving as a semiconductor encapsulant, any epoxy resin may be used as the liquid epoxy resin (A) as long as it contains two or less epoxy functional groups in a molecule and is liquid at normal temperature. Preferably the liquid epoxy resin has a viscosity at 25° C. of up to 2,000 poises, especially up to 500 poises. Useful liquid epoxy resins include bisphenol type epoxy resins such as bisphenol A epoxy resins and bisphenol F epoxy resins, naphthalene type epoxy resins and phenyl glycidyl ether. Of these, epoxy resins which are liquid at room temperature are desirable. It is acceptable to add another epoxy resin of the structure shown below to these liquid epoxy resins insofar as infiltration ability is not compromised.

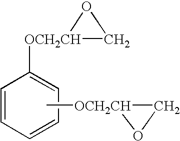

The liquid epoxy resin preferably has a total chlorine content of not more than 1,500 ppm, and especially not more than 1,000 ppm. When chlorine is extracted from the epoxy resin with water at an epoxy resin concentration of 50% and a temperature of 100° C. over a period of 20 hours, the water-extracted chlorine content is preferably not more than 10 ppm. At a total chlorine content of more than 1,500 ppm or a water-extracted chlorine level of more than 10 ppm, the reliability of the sealed semiconductor device, particularly in the presence of moisture, may be compromised.

The aromatic amine curing agent (B) used herein contains at least 5% by weight, preferably 10 to 100% by weight, more preferably 20 to 100% by weight, based on the entire curing agent, of at least one aromatic amine compound having a purity of at least 99% selected from compounds having the general formulae (1) to (3). If the content of the aromatic amine compounds having formulae (1) to (3) is less than 5% by weight based on the entire curing agent, adhesive strength lowers and cracks generate. If the purity of the aromatic amine compound is less than 99%, a disgusting odor is given off, exacerbating the working environment. As used herein, the “purity” refers to that of a monomer.

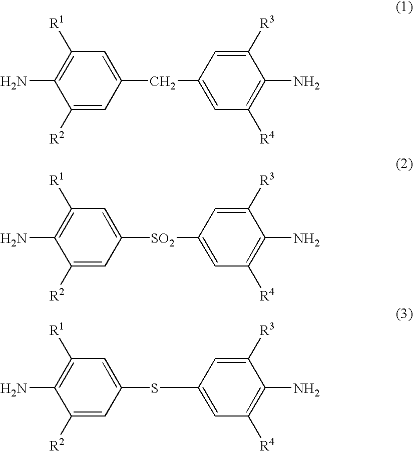

Herein each of R¹ to R⁴ is hydrogen or a monovalent hydrocarbon group having 1 to 6 carbon atoms. The monovalent hydrocarbon groups represented by R¹ to R⁴ are preferably those having 1 to 6 carbon atoms, more preferably 1 to 3 carbon atoms, for example, alkyl groups such as methyl, ethyl, propyl, isopropyl, butyl, isobutyl, tert-butyl and hexyl, alkenyl groups such as vinyl, allyl, propenyl, butenyl and hexenyl, phenyl groups, and halo-substituted monovalent hydrocarbon groups in which some or all of the hydrogen atoms are substituted with halogen atoms (e.g., chlorine, fluorine and bromine), such as fluoromethyl, bromoethyl and trifluoropropyl.

The curing agents other than the aromatic amine curing agent are preferably low molecular weight aromatic amines such as 2,4-diaminotoluene, 1,4-diaminobenzene and 1,3-diaminobenzene.

Since the aromatic amine curing agent is generally solid at normal temperature, direct compounding of the aromatic amine curing agent with the epoxy resin results in a resin compound which has an increased viscosity and is awkward to work. It is then preferred to previously melt and mix the aromatic amine curing agent with the epoxy resin, more preferably in a predetermined proportion at a temperature in the range of 70 to 150° C. for 1 to 2 hours. At a mixing temperature below 70° C., the aromatic amine curing agent may be less compatible with the epoxy resin. A temperature above 150° C. can cause the aromatic amine curing agent to react with the epoxy resin to increase its viscosity. A mixing time of less than 1 hour is insufficient to render the aromatic amine curing agent compatible, inviting a viscosity increase. A time of more than 2 hours may allow the aromatic amine curing agent to react with the epoxy resin to increase its viscosity.

The total amount of the aromatic amine curing agent used herein should be such that the molar ratio of the liquid epoxy resin to the aromatic amine curing agent, (A)/(B), is in the range from 0.7/1 to 0.9/1, preferably from 0.7/1 to less than 0.9/1, more preferably from 0.7/1 to 0.85/1. If the compounding molar ratio is less than 0.7, unreacted amine groups are left, resulting in a lower glass transition temperature and poor adhesion. With a molar ratio in excess of 0.9, the K_{1c} value lowers and the cured product becomes hard and brittle enough for cracks to form during the reflow operation.

As the inorganic filler (C) in the inventive composition, any inorganic filler known to be useful for lowering the expansion coefficient may be added. Specific examples include fused silica, crystalline silica, aluminum, alumina, aluminum nitride, boron nitride, silicon nitride, magnesia and magnesium silicate. Of these, spherical fused silica is desirable for achieving low viscosity. The inorganic filler may have been surface treated with a silane coupling agent or the like although the inorganic filler can be used without surface treatment.

When the liquid epoxy resin composition is used as a potting material, the inorganic filler desirably has an average particle size of 2 to 20 μm and a maximum particle size of preferably up to 75 μm, more preferably up to 50 μm. A filler with an average particle size of less than 2 μm may provide an increased viscosity and cannot be loaded in large amounts. An average particle size of more than 20 μm means the inclusion of a more proportion of coarse particles which will catch on lead wires, causing voids.

The amount of the inorganic filler included in the composition is in a range of preferably 100 to 600 parts by weight per 100 parts by weight of the epoxy resin. With less than 100 parts by weight of the filler, the expansion coefficient tends to be too large, which may cause cracks to form in a thermal cycling test. More than 600 parts by weight of the filler increases the viscosity, which may bring about a decline in flow.

When the liquid epoxy resin composition is used as an underfill which should exhibit both improved penetration and a lower linear expansion, it is advantageous to include an inorganic filler having an average particle size at most about one-tenth as large and a maximum particle size at most one-half as large as the size of the flip chip gap (between the substrate and semiconductor chip in a flip chip semiconductor device). In this embodiment, the amount of inorganic filler included in the composition is in a range of preferably 50 to 400 parts by weight, and especially 100 to 250 parts by weight, per 100 parts by weight of the epoxy resin. A composition with less than 50 parts by weight of the filler may have too large an expansion coefficient and crack in a thermal cycling test. A composition with more than 400 parts by weight of the filler may have an increased viscosity, which may bring about a decline in thin-film penetration.

In the liquid epoxy resin composition of the invention, silicone rubbers, silicone oils, liquid polybutadiene rubbers, and thermoplastic resins such as methyl methacrylate-butadiene-styrene copolymers may be included for the stress reduction purpose. Preferably, the stress reducing agent is a silicone-modified resin in the form of a copolymer which is obtained from an alkenyl group-containing epoxy resin or alkenyl group-containing phenolic resin and an organopolysiloxane of the average compositional formula (4) containing per molecule 20 to 400 silicon atoms and 1 to 5 hydrogen atoms each directly attached to a silicon atom (i.e., SiH groups), by effecting addition reaction between alkenyl groups and SiH groups.
HₐR⁵_{b}SiO_{(4-a-b)/2} (4)
Herein R⁵ is a substituted or unsubstituted monovalent hydrocarbon group, “a” is a number of 0.01 to 0.1, “b” is a number of 1.8 to 2.2, and the sum of a+b is from 1.81 to 2.3.

The monovalent hydrocarbon group represented by R⁵ preferably has 1 to 10 carbons, and especially 1 to 8 carbons. Illustrative examples include alkyl groups such as methyl, ethyl, propyl, isopropyl, butyl, isobutyl, tert-butyl, hexyl, octyl and decyl; alkenyl groups such as vinyl, allyl, propenyl, butenyl and hexenyl; aryl groups such as phenyl, xylyl and tolyl; aralkyl groups such as benzyl, phenylethyl and phenylpropyl; and halogenated monovalent hydrocarbon groups in which some or all of the hydrogen atoms on the hydrocarbon groups have been substituted with halogen atoms (e.g., chlorine, fluorine, bromine), such as fluoromethyl, bromoethyl and trifluoropropyl.

Copolymers having the following structure are preferred. 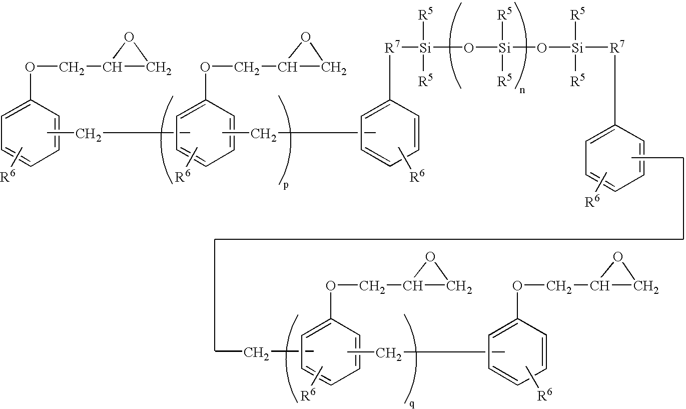
In the above formula, R⁵ is as defined above, R⁶ is a hydrogen atom or an alkyl of 1 to 4 carbons, and R⁷ is —CH₂CH₂CH₂—, —OCH₂—CH(OH)—CH₂—O—CH₂CH₂CH₂— or —O—CH₂CH₂CH₂—. The letter n is an integer from 4 to 199, and preferably from 19 to 99, p is an integer from 1 to 10, and q is an integer from 1 to 10.

The above-described copolymer is included in the inventive composition such that the amount of diorganopolysiloxane units is 0 to 20 parts by weight, and preferably 2 to 15 parts by weight, per 100 parts by weight of the epoxy resin, whereby stress can be further reduced.

If necessary, the liquid epoxy resin composition may further contain other additives as long as they do not compromise the objects of the invention. Suitable additives include carbon-functional silanes for improving adhesion, pigments (e.g., carbon black), dyes, and antioxidants. It is recommended that the addition of an alkoxy-bearing silane coupling agent as the carbon functional silane adhesion improver is excluded from the present invention although such a coupling agent can be used as the surface treating agent for the filler. Particularly when the composition is used as an underfill, compounding the alkoxy-bearing silane coupling agent, even in a minor amount, can cause void formation.

The liquid epoxy resin composition of the invention may be prepared by the simultaneous or discrete agitation, melting, mixing and dispersion of the liquid epoxy resin, aromatic amine curing agent and inorganic filler as well as optional additives, while carrying out heat treatment if necessary. No particular limitation is imposed on the apparatus used for mixing, agitating, dispersing and otherwise processing the mixture of components. Exemplary apparatus suitable for this purpose include an automated mortar, three-roll mill, ball mill and planetary mixer. Use can also be made of suitable combinations of these apparatuses.

The liquid epoxy resin composition of the invention should have a toughness K_{1c} of at least 3.5, preferably at least 4.0. A composition with a toughness K_{1c} of less than 3.5 may be weak to thermal shocks and thermal cycling.

Also the liquid epoxy resin composition for use as a sealant or encapsulant should desirably have a viscosity of up to 10,000 poises at 25° C.

An ordinary molding method and ordinary molding conditions may be employed when encapsulating semiconductor devices with the inventive composition. It is preferable to carry out an initial hot oven cure at about 100 to 120° C. for at least about ½ hour, followed by a subsequent hot oven cure at about 150° C. for at least about ½ hour. Initial curing conditions below the above-mentioned temperature and time may result in void formation after curing, and subsequent curing conditions below the temperature and time indicated above may yield a cured product having less than sufficient properties.

The semiconductor devices to be encapsulated with the inventive composition are typically flip chip-type semiconductor devices. Referring to FIG. 1, the flip chip-type semiconductor device includes an organic substrate 1 having an interconnect pattern side on which is mounted a semiconductor chip 3 over a plurality of intervening bumps 2. The gap between the organic substrate 1 and the semiconductor chip 3 (shown in the diagram as gaps between the bumps 2) is filled with an underfill material 4, and the lateral edges of the gap and the periphery of semiconductor chip 3 are sealed with a fillet material 5. The inventive liquid epoxy resin composition is especially suitable in forming the underfill.

When the inventive composition is used as an underfill material, the cured product preferably has an expansion coefficient of 20 to 40 ppm/° C. below the glass transition temperature (Tg).

Sealant used as the fillet material may be a conventional material known to the art. The use as the fillet of a liquid epoxy resin composition of the same type as the present invention is especially preferred. The cured product in this case preferably has an expansion coefficient of 10 to 20 ppm/° C. below the Tg.

### EXAMPLE

Examples of the invention and comparative examples are given below by way of illustration, and are not intended to limit the invention.

### Examples 1-5 and Comparative Examples 1-3

The components shown in Table 1 were mixed to uniformity on a three-roll mill to give eight resin compositions. These resin compositions were examined by the following tests. The results are also shown in Table 1.

Viscosity

The viscosity at 25° C. was measured using a BH-type rotary viscometer at a rotational speed of 4 rpm.

Void Test

A polyimide-coated silicon chip of 10 mm×10 mm was placed on a FR-4 substrate of 30 mm×30 mm using spacers of approximately 100 μm thick, leaving a gap therebetween. The composition was introduced into the gap and cured thereat. Using a scanning acoustic microscope C-SAM (SONIX Inc.), the sample was inspected for voiding.

Toughness K_{1c}

The toughness K_{1c} at normal temperature was measured according to ASTM D5045.

Glass Transition Temperature (Tg)

Using a sample of the cured composition measuring 5×5×15 mm, the glass transition temperature was measured with a thermomechanical analyzer at a heating rate of 5° C./min. Coefficients of Thermal Expansion (CTE)

Based on the Tg measurement described above, a coefficient of thermal expansion below Tg (CTE-1) was determined for a temperature range of 50 to 80° C., and a coefficient of thermal expansion above Tg (CTE-2) was determined for a temperature range of 200 to 230° C.

Bond Strength Test

On a photosensitive polyimide-coated silicon chip was rested a frustoconical sample having a top diameter of 2 mm, a bottom diameter of 5 mm and a height of 3 mm. It was cured at 150° C. for 3 hours. At the end of curing, the sample was measured for (initial) shear bond strength. The cured sample was then placed in a pressure cooker test (PCT) environment of 121° C. and 2.1 atm for 336 hours for moisture absorption. At the end of PCT test, shear bond strength was measured again. In each Example, five samples were used, from which an average bond strength value was calculated.

PCT Peel Test

A polyimide-coated 10×10 mm silicon chip was stacked on a 30×30 mm FR-4 substrate using spacers of approximately 100 μm thick, leaving a gap therebetween. An epoxy resin composition was introduced into the gap and cured thereat. The assembly was held at 30° C. and RH 65% for 192 hours and then processed 5 times by IR reflow set at a maximum temperature of 265° C., before the assembly was checked for peeling. The assembly was then placed in a PCT environment of 121° C. and 2.1 atm for 336 hours, before the assembly was checked for peeling. Peeling was inspected by C-SAM (SONIX Inc.).

Thermal Shock Test

A polyimide-coated 10×10 mm silicon chip was stacked on a 30×30 mm FR-4 substrate using spacers of approximately 100 μm thick, leaving a gap therebetween. An epoxy resin composition was introduced into the gap and cured thereat. The assembly was held at 30° C. and RH 65% for 192 hours and then processed 5 times by IR reflow set at a maximum temperature of 265° C. The assembly was then tested by thermal cycling between −65° C./30 minutes and 150° C./30 minutes. After 250, 500 and 750 cycles, the assembly was examined for peeling and cracks.

TABLE 1

| Component | Example | | | | | Comparative Example | | |
|---|---|---|---|---|---|---|---|---|
| (pbw) | 1 | 2 | 3 | 4 | 5 | 1 | 2 | 3 |
| C-100S | 30 | | | 15 | | | 20 | 40 |
| C-300S | | 35 | | 20 | 20 | | | |
| Seika Cure-S | | | 32 | | 10 | | | |
| RE303S-L | 70 | 65 | 68 | 75 | 70 | 50 | 80 | 60 |
| MH700 | | | | | | 30 | | |
| YH307 | | | | | | 20 | | |
| Spherical silica | 150 | 150 | 150 | 150 | 150 | 150 | 150 | 150 |
| KBM403 | | | | | | 1.0 | | |
| Copolymer | 4 | 4 | 4 | 4 | 4 | 4 | 4 | 4 |
| 2E4MZ | | | | | | 1 | | |
| Epoxy resin/amine | 0.8 | 0.8 | 0.8 | 0.8 | 0.8 | — | 1.0 | 0.6 |
| curing agent molar | | | | | | | | |
| ratio | | | | | | | | |

Measurement results

| | | | | | | | | |
|---|---|---|---|---|---|---|---|---|
| Viscosity at | 75.6 | 56.6 | 66.3 | 72.5 | 73 .4 | 28.4 | 64.3 | 108 |
| 25° C. (Pa · s) | | | | | | | | |
| Void test | nil | nil | nil | nil | nil | nil | nil | nil |
| Toughness K_{1c} | 4.3 | 4.2 | 4.1 | 4.3 | 4.2 | 2.6 | 3.4 | 2.9 |
| Tg (° C.) | 125 | 122 | 110 | 105 | 108 | 140 | 138 | 86 |
| CTE-1 (ppm/° C.) | 32 | 31 | 33 | 32 | 31 | 31 | 29 | 35 |
| CTE-2 (ppm/° C.) | 122 | 115 | 113 | 114 | 119 | 113 | 105 | 144 |
| PCT peel test | | | | | | | | |
| After 5 times | no | no | no | no | no | peeled | no | peeled |
| of IR reflow | peeling | peeling | peeling | peeling | peeling | | peeling | |
| at 265° C. | | | | | | | | |
| After PCT 336 hr | no | no | no | no | no | peeled | peeled | peeled |
| | peeling | peeling | peeling | peeling | peeling | | | |
| Bond strength | | | | | | | | |
| (kgf/cm²) | | | | | | | | |
| Initial | 256 | 248 | 255 | 243 | 255 | 182 | 198 | 133 |
| After | 206 | 199 | 203 | 187 | 189 | 95 | 95 | 56 |
| PCT 336 hr | | | | | | | | |
| Failure (%) after | | | | | | | | |
| thermal shock test | | | | | | | | |
| 250 cycles | 0 | 0 | 0 | 0 | 0 | 50 | 0 | 0 |
| 500 cycles | 0 | 0 | 0 | 0 | 0 | 100 | 0 | 40 |
| 750 cycles | 0 | 0 | 0 | 0 | 0 | — | 10 | 100 |

Components:
C-100S: diethyldiaminophenylmethane, Nippon Kayaku Co., Ltd.
C-300S: tetraethyldiaminophenylmethane, Nippon Kayaku Co., Ltd.
Seika Cure-S: 4,4′-diaminodiphenylsulfone, Wakayama Seika Kogyo Co., Ltd.
RE303S-L: bisphenol F-type epoxy resin, Nippon Kayaku Co., Ltd.
MH700: methyltetrahydrophthalic anhydride, New Japan Chemical Co., Ltd.
YH307: a mixture of 3,4-dimethyl-6-(2-methyl-1-propenyl)-1,2,3,6-tetrahydrophthalic acid and 1-isopropyl-4-methyl-bicyclo[2.2.2]oct-5-ene-2,3-dicarboxylic acid in a weight ratio of 6/4, Japan Epoxy Resins Co., Ltd.
KBM403: silane coupling agent, γ-glycidoxypropyltrimethoxy-silane, Shin-Etsu Chemical Co., Ltd.
2E4MZ: 2-ethyl-4-methylimidazole, Shikoku Chemicals Co., Ltd. Spherical silica: spherical silica having a maximum particle size of up to 24 μm and an average particle size of 6 μm
Copolymer: the addition reaction product of

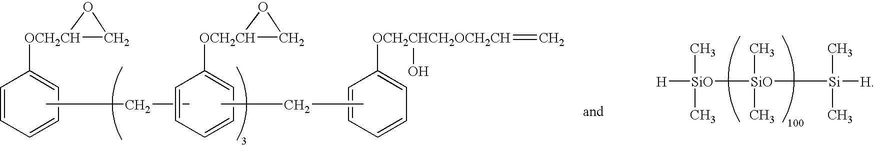

It has been demonstrated that the liquid epoxy resin composition of the invention cures into a cured product which has improved adhesion to the surface of silicon chips and especially to photosensitive polyimide resins and nitride films, and offers an encapsulated semiconductor device that does not suffer a failure even when the temperature of reflow after moisture absorption elevates from the conventional temperature of nearly 240° C. to 260-270° C., does not deteriorate under hot humid conditions as encountered in PCT (120° C./2.1 atm), and does not undergo peeling or cracking over several hundred cycles of thermal cycling between −65° C. and 150° C. The composition is thus best suited as an encapsulant for semiconductor devices.

Japanese Patent Application No. 2002-209437 is incorporated herein by reference.

Although some preferred embodiments have been described, many modifications and variations may be made thereto in light of the above teachings. It is therefore to be understood that the invention may be practiced otherwise than as specifically described without departing from the scope of the appended claims.

1. A liquid epoxy resin composition comprising:
(A) a liquid epoxy resin;
(B) an aromatic amine curing agent;
(C) an inorganic filler; and
(D) a silicone-modified resin, wherein
the aromatic amine curing agent (B) comprises at least 5% by weight based on the entire curing agent of at least one aromatic amine compound having a purity of at least 99% selected from compounds having the following general formulae (1) to (3): 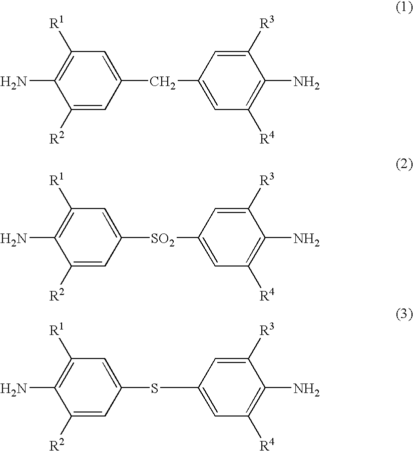
wherein each of R¹ to R⁴ is hydrogen or a monovalent hydrocarbon group having 1 to 6 carbon atoms,
the liquid epoxy resin (A) and the aromatic amine curing agent (B) are present in a molar ratio (A)/(B) from 0.7/1 to 0.9/1, and
the silicone-modified resin is in the form of a copolymer which is obtained from an alkenyl group-containing epoxy resin or phenolic resin and an organopolysiloxane having the average compositional formula (4):
HₐR⁵_{b}SiO_{(4-a-b)/2} (4)
wherein R⁵ is a substituted or unsubstituted monovalent hydrocarbon group, “a” is a number of 0.01 to 0.1, “b” is a number of 1.8 to 2.2, and 1.81≦a+b≦2.3, said organopolysiloxane containing per molecule 20 to 400 silicon atoms and 1 to 5 hydrogen atoms each directly attached to a silicon atom (i.e., SiH groups), by effecting addition reaction between alkenyl groups and SiH groups,
the composition has a toughness K_{1c} of at least 3.5.

2. The composition of claim 1, which is free of an alkoxy-bearing silane coupling agent except that an alkoxy-bearing silane coupling agent is used for the surface treatment of the inorganic filler.

3. The composition of claim 1, wherein the liquid epoxy resin (A) and the aromatic amine curing agent (B) are present in a molar ratio (A)/(B) of from 0.7/1 to 0.85/1.

4. The composition of claim 1, wherein the composition has a toughness K_{1c} of at least 4.0.

5. The composition of claim 1, wherein the inorganic filler is spherical silica.

6. A semiconductor device which is encapsulated with the liquid epoxy resin composition of claim 1 in the cured state.

7. A flip chip type semiconductor device which is encapsulated with the liquid epoxy resin composition of claim 1 in the cured state as an underfill.
